(19) United States
(12) Patent Application Publication
(10) Pub. No.: US 2007/0290216 A1
(43) Pub. Date: Dec. 20, 2007

(54) Semiconductor light emitting element, manufacturing method therefor, and compound semiconductor light emitting diode

(75) Inventor: Nobuyuki Watanabe, Mihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/812,499

(22) Filed: Jun. 19, 2007

(30) Foreign Application Priority Data
Jun. 20, 2006 (JP) 2006-169700

(51) Int. Cl. H01L 33/00

(52) U.S. Cl. 257/86

(57) ABSTRACT

A semiconductor light emitting element is provided with a transparent substrate for improving the optical extraction efficiency by using a transparent substrate. The semiconductor light emitting element includes a main body constructed of an n-Al_{0.6}Ga_{0.4}As current diffusion layer, an n-Al_{0.5}In_{0.5}P cladding layer, an AlGaInP active layer, a p-Al_{0.5}In_{0.5}P cladding layer, a p-GaInP interlayer and a p-GaP contact layer. An n-GaP transparent substrate is placed under the main body. A p-GaP transparent substrate is placed on top of the main body. The n-GaP transparent substrate and the p-GaP transparent substrate have transparency with respect to light emitted from the AlGaInP light emitting layer.

### CROSS-REFERENCE TO RELATED APPLICATION

This nonprovisional application claims priority under 35 U.S.C. §119(a) on Patent Application No. 2006-169700 filed in Japan on 20 Jun. 2006, the entire contents of which are incorporated herein by reference.

### BACKGROUND OF THE INVENTION

The present invention relates to a semiconductor light emitting element, a manufacturing method therefor and a compound semiconductor light emitting diode, where these luminous bodies are necessary for communications such as display boards of roads, railway tracks and guides, advertising displays, portable telephones, back lights of displays, lighting fixtures and so on.

In recent years, rapid progress has been made in manufacturing technologies of the semiconductor light emitting diode (hereinafter referred to as “LED”) that is one of semiconductor light emitting elements. After development of a blue LED in particular, three primary colors of light are made available in LEDs, so that it has become possible to produce light of all wavelengths by combining the LEDs of the three primary colors.

Thus, the application range of LEDs has rapidly widespread. Among others, LEDs are attracting attention as new sources of natural light and white light sources substituting for bulbs and fluorescent lamps in the field of lighting, conjointly with improvements in the sense of environment and energy problems.

However, the current LEDs have inferior conversion efficiency of light with respect to the input energy compared to the bulbs and fluorescent lamps. Researches and developments aimed at higher conversion efficiency and higher luminance of LEDs have been conducted regardless of wavelengths.

In the past, the technological developments for increasing the luminance of LEDs have been centered on the epitaxial growth technology. As the result, the efficiency of light emission inside the crystals (internal quantum efficiency) has been increased by the band structure optimization of the multiquantum well structure and so on, so that the epitaxial growth technology is maturing. On the above background, in recent years, the center of the technological developments for increasing the luminance of LEDs is shifting to the processing technologies.

The improvement of luminance in the processing technologies is substantially the improvement in the external extraction efficiency, specifically, the improvement in fine processing technology of the element shape, reflection coating, transparent electrode and so on. Among others, some techniques using the wafer bonding method have been established in red and blue light emitting LEDs, so that the high-intensity type LEDs have been invented and put on the market.

There are mainly two types of techniques for increasing the luminance by wafer bonding. One is a technique for affixing an opaque substrate of silicon or germanium to an epitaxial layer directly or via a metal layer. The other is a technique for affixing a substrate transparent to light of emission wavelength, such as glass, sapphire or GaP, to an epitaxial layer directly or via an adhesive layer.

In the former, the affixed substrate or metal layer functions as a reflecting layer. The layer has an effect of outwardly reflecting the light before the light is absorbed by the substrate for epitaxial growth. This outward reflection improves the luminance. In the latter, the light is taken outside via the transparent substrate so as to increase the external extraction efficiency of light.

FIG. 1 is a schematic sectional view of a semiconductor light emitting element as an example of the former, which includes a silicon substrate 101, a reflection metal 102, a light emitting layer 103 and electrodes 104, 105.

FIG. 2 is a schematic sectional view of a semiconductor light emitting element as an example of the latter, which includes a transparent substrate 201, a light emitting layer 202, a window layer 203 and electrodes 204, 205.

The latter technique, i.e., the affixing technique of the transparent substrate uses no reflection. Therefore, light does not pass through the light emitting layer again. With this arrangement, the light is not absorbed by the light emitting layer when the light passes through the light emitting layer again.

Thus, the affixing technique of the transparent substrate makes it possible to take the light outside from almost the entire surface of the semiconductor light emitting element, so that LEDs having a higher conversion efficiency (extraction efficiency) can be developed.

As a quaternary system LED using the conventional affixing technique of the transparent substrate, there is a LED in which a GaP (gallium phosphide) transparent substrate is affixed directly to an AlGaInP (aluminum gallium indium phosphide) based semiconductor layer. This is described in JP3230638, JP3705791 and so on.

However, in the case of the conventional affixing technique of the transparent substrate, the transparent substrate is normally affixed to only one surface of the semiconductor laminate structure. On the other surface, there is formed an epitaxial growth layer like a current diffusion layer or a window layer.

However, in the case where the transparent substrate is affixed to only one surface of the semiconductor laminate structure, although the extraction efficiency of light from the transparent substrate layer side is improved, the light emitted from the light emitting layer is absorbed by the epitaxial growth layer on the side opposite from the transparent substrate layer side. Accordingly, there is a problem of decrease in the extraction efficiency of light from the side opposite from the transparent substrate layer side.

Moreover, even when light is taken out from the transparent substrate side, the epitaxial growth layer itself has a multilayer structure, and therefore, reflection to the inside occurs due to a refractive index difference between the layers of the multilayer structure. Consequently, this leads to a problem that the light attenuates while the light repeats reflections between the epitaxial layers.

Moreover, all the light is not emitted from the entire surface of the transparent substrate on the side where the transparent substrate is placed. The light is reflected at an interface between the transparent substrate and air, and also at an interface between the transparent substrate and resin in the case where the transparent substrate is molded with resin. Thus, the light attenuates since reflection of light repeats in the semiconductor layer or the transparent substrate.

In terms of the manufacturing method, there is a problem of cost increase due to difficulties in securing a sufficient thickness of the current diffusion layer (due to epitaxial growth), for example.

### SUMMARY OF THE INVENTION

An object of the present invention is to provide a semiconductor light emitting element capable of improving the optical extraction efficiency by employing a transparent substrate, a manufacturing method therefor and a compound semiconductor light emitting diode.

A semiconductor light emitting element comprising:

a main body having a first conductive type semiconductor layer, a light emitting layer provided on the first conductive type semiconductor layer and a second conductive type semiconductor layer provided on the light emitting layer;

a first transparent substrate placed directly or indirectly under the main body and having transparency with respect to light emitted from the light emitting layer; and

a second transparent substrate placed directly or indirectly on top of the main body and having transparency with respect to the light emitted from the light emitting layer.

In this case, a first conductive type is p-type or n-type. A second conductive type is the n-type when the first conductive type is the p-type, or is the p-type when the first conductive type is the n-type.

According to the semiconductor light emitting element stated above, it is possible to efficiently take light to the outside via the first and second transparent substrates. This is because the first transparent substrate, which has transparency with respect to light emitted from the light emitting layer, is directly or indirectly placed under the main body and because the second transparent substrate, which has transparency with respect to light emitted from the light emitting layer, is directly or indirectly placed on top of the main body. That is, the optical extraction efficiency can be improved.

In this case, the first and second conductive type semiconductor layers are each formed as a cladding layer for example, and the light emitting layer is made as a multiquantum well structure for example. Thereby, the number of layers that constitute the main body can be made the bare minimum.

The decrease in the number of layers constituting the main body allows preventing repetition of internal reflection. Therefore, it is possible to more efficiently take light to the outside via the first and second transparent substrates.

As long as light can wholly or partially pass through the transparent substrate interface, the first transparent substrate and the second transparent substrate may be placed by using direct affixation or indirect affixation via an adhesive, a metal, an oxide, a nitride or the like.

In one embodiment of the present invention, the first transparent substrate is comprised of a first conductive type semiconductor, and the second transparent substrate is comprised of a second conductive type semiconductor.

According to the semiconductor light emitting element of the embodiment, the first transparent substrate is electrically connected to the first conductive type semiconductor layer. The second transparent substrate is electrically connected to the second conductive type semiconductor layer. The first transparent substrate is constructed of the first conductive type semiconductor, and the second transparent substrate is constructed of the second conductive type semiconductor. An electrode is formed on each of the first transparent substrate and the second transparent substrate. Thus, light emission is obtained by electrification to the electrodes.

Also, in the semiconductor light emitting element of the embodiment, the first and second transparent substrates may be placed by direct affixation or indirect affixation via an adhesive, a metal, an oxide, a nitride or the like as long as light can wholly or partially pass through the transparent substrate interface.

FIG. 3 is a schematic sectional view of one example of the direct bonding of the semiconductor light emitting element of the above embodiment. The semiconductor light emitting element includes a p-type GaP transparent substrate 301, a p-type GaP contact layer 302, a p-type AlInP cladding layer 303, an AlGaInP active layer 304, an n-type AlInP cladding layer 305, an n-type GaP contact layer 306, an n-type GaP transparent substrate 307 and electrodes 308, 309.

FIG. 4 is a schematic view of one example of the indirect affixation of a semiconductor light emitting element of the above embodiment. The semiconductor light emitting element includes a p-type GaP transparent substrate 401, a p-type GaP contact layer 402, a p-type AlInP cladding layer 403, an AlGaInP active layer 404, an n-type AlInP cladding layer 405, an n-type GaP contact layer 406, an n-type GaP transparent substrate 407, electrodes 408, 409 and contact layers 410, 411. The contact layers 410, 411 are formed by using at least one of an adhesive, a metal, an oxide, a nitride and the like.

In FIGS. 3 and 4, the light emitting layer is made of GaAlInP, and the transparent substrate is made of GaP. However, in the present invention, the light emitting layer may be made of a material other than GaAlInP, and also the transparent substrate may be made of a material other than GaP.

In one embodiment of the present invention, the first transparent substrate is of a second conductive type; or the second transparent substrate is of a first conductive type; or the first transparent substrate is of the second conductive type, and the second transparent substrate is of the first conductive type.

According to the semiconductor light emitting element of the embodiment, at least one of the first transparent substrate and the second transparent substrate is not electrically connected to an abutting semiconductor layer. This is because the conductive type of the first transparent substrate is the second conductive type; or the conductive type of the second transparent substrate is the first conductive type; or the conductive type of the first transparent substrate is the second conductive type and the conductive type of the second transparent substrate is the first conductive type. That is, at least one of the first transparent substrate and the second transparent substrate forms a p-n junction with the abutting semiconductor layer. A neutral region (depletion layer) is formed in terms of polarity at the interface that has the p-n junction, and no current flows unless a definite voltage is applied.

Therefore, a semiconductor light emitting element of a two-wire type or a flip type (surface mount type) can be fabricated by forming an electrode on at least one of the first transparent substrate and the second transparent substrate and forming an electrode in a portion other than the first transparent substrate and the second transparent substrate.

In the semiconductor light emitting element of the above embodiment, the substrate, which is electrically connected, of the first transparent substrate and the second transparent substrate may be placed by using direct affixation or indirect affixation via an adhesive, a metal, an oxide, a nitride or the like as long as light can wholly or partially pass through the substrate interface. Also, the substrate, on which the p-n junction is formed, of the first transparent substrate and the second transparent substrate may be placed by using direct affixation or indirect affixation via an adhesive, an oxide, a nitride or the like as long as light can wholly or partially pass through the substrate interface.

In the semiconductor light emitting element of the above embodiment, the first transparent substrate and the second transparent substrate may be placed by direct affixation or indirect affixation via an adhesive, a metal, an oxide, a nitride or the like as long as light can wholly or partially pass through the transparent substrate interface.

FIG. 5 is a schematic structural view of one example of the semiconductor light emitting element of the above embodiment. The semiconductor light emitting element includes an n-type GaP transparent substrate 501, a p-type GaP contact layer 502, a p-type AlInP cladding layer 503, an AlGaInP active layer 504, an n-type AlInP cladding layer 505, an n-type GaP contact layer 506, an n-type GaP transparent substrate 507 and electrodes 508, 509.

In one embodiment of the present invention, at least one of the first transparent substrate and the second transparent substrate has a carrier density of not higher than 2.5×10¹⁸ cm⁻³.

FIGS. 6 and 7 show experimental results of carrier densities (1) 1.5×10¹⁸ cm⁻³ and (2) 5.0×10¹⁷ cm⁻³ of a p-type (zinc-doped) GaP substrate that serves as one example of the first transparent substrate or the second transparent substrate.

FIG. 6 shows the experimental results of transmittance of the single body of the GaP transparent substrate that is one example of the first transparent substrate or the second transparent substrate. Since the reflection at each interface of light incident on the GaP transparent substrate is not taken into consideration, the transmittance on the lower energy side than the band gap comes to have a value of about 50% (actual transmittance is not smaller than about 90%).

Thickness of the GaP transparent substrate itself is very thin (about 250 μm). Therefore, the transmittance is varied by several percent between the GaP transparent substrate of the carrier density (1) and the GaP transparent substrate of the carrier density (2). On the basis of the results and the following general formula of transmittance:

Transmittance=I/I₀=exp(−αd)
where I₀: Initial quantity of light,
   I: Quantity of transmitted light, and
   d: Thickness,
      the absorption coefficients α of light at a wavelength of 640 nm were calculated with regard to the carrier densities (1) and (2) of GaP.

The absorption coefficient of the GaP transparent substrate was 3.30 cm⁻¹ in the case of (1) 1.5×10¹⁸ cm⁻³.

The absorption coefficient of the GaP transparent substrate was 5.46×10⁻² cm⁻¹ in the case of (2) 5.0×10¹⁷ cm⁻³.

Next, FIG. 7 shows transmittance dependency on thickness as calculation results when light passes through the substrates having the absorption coefficients in the cases of the carrier densities (1) and (2). Light naturally attenuates as the path length increases.

When a transparent substrate is placed, light emitted from the light emitting layer includes a component that is directly taken to the outside and a component that is reflected at the interfaces between the substrate crystals and other material and between the substrate crystals and the outside. Much of light repeats reflections within the transparent substrate.

Therefore, it is clear that light passes over a distance of not smaller than the thickness of the transparent substrate. Light attenuates as the light path length increases, consequently reducing the external extraction efficiency.

Setting of the carrier density according to the present invention allows reduction of such attenuation as much as possible. Attenuation of light is mainly caused by free carriers. Therefore, the setting of the carrier density according to the present invention can be applied to all sorts of crystals, compounds and materials regardless of any kinds of the substrates, dopants and so on.

In one embodiment of the present invention, at least one of the first transparent substrate and the second transparent substrate is comprised of an insulator.

According to the semiconductor light emitting element of the embodiment, insulation to the mounting surface can be achieved in mounting by constituting at least one of the first transparent substrate and the second transparent substrate of an insulator. This makes it possible to use a low refractive index material for improving the compatibilities with air and/or the molding resin.

Glass, sapphire or the like is used as an insulator. The construction shown in FIG. 5 may be used as the construction of the semiconductor light emitting element of the above embodiment.

In one embodiment of the present invention, at least one of the first transparent substrate and the second transparent substrate has a slope surface inclined to the upper surface of the light emitting layer.

FIG. 8 is a schematic sectional view of one example of the semiconductor light emitting element of the above embodiment. The semiconductor light emitting element includes a p-type GaP transparent substrate 801, a p-type GaP contact layer 802, a p-type AlInP cladding layer 803, an AlGaInP active layer 804, an n-type AlInP cladding layer 805, an n-type GaP contact layer 806, an n-type GaP transparent substrate 807 and electrodes 808, 809.

In order to take light to the outside of the semiconductor light emitting element, it is generally necessary to make light incident under the condition that no reflection occurs at the interface with the outside such as air or resin. Specifically, when the incidence angle is perpendicular to the interface, light goes out to the outside without occurrence of reflection at the interface. Therefore, it is ideal that the shape of the interface is round (spherical) in order to satisfy the above conditions with respect to all directions of light emission. In other words, it is ideal that the cross-sectional shape of the interface is a circular arc.

FIG. 9 is a schematic view of the essential part of one example of the semiconductor light emitting element that has an interface of a circular arc shape. In this case, the luminescence source of the semiconductor light emitting element is a point light source.

It is ideal that the first and second transparent substrates are processed into a spherical shape in the present invention. Then, it is also necessary that the light emitting layer is a point light source.

FIG. 10 shows a processed shape of the transparent substrate of the present invention as an example, assuming that the light emitting layer is a point light source.

In FIG. 10, it is assumed that the light emitting layer is a semiconductor layer made of AlGaInP and that the emission wavelength is 640 nm corresponding to a red color. In FIG. 10, the light emitting layer and only one of the transparent substrates are shown, and it is assumed that the transparent substrate is made of GaP. Due to a refractive index difference between GaP and air, light is totally reflected and directed inward when the incidence angle of light incident on the interface between the transparent substrate and air becomes 17.6° or more. Considering this fact, an optimal example of the shape of the transparent substrate is one as shown in FIG. 10.

On the other hand, the shape of the transparent substrate becomes one as shown in FIG. 11 when the refractive index difference is taken into consideration as in a case where the semiconductor light emitting element is molded in a resin or the like. The shape of the transparent substrate is not limited to the shape of FIG. 11, but may have a simple slope shape as shown in FIG. 12 because total reflection occurs at an incidence angle of about 30°.

It should be noted that the shapes of the transparent substrate as shown in FIGS. 10 through 12 or their processing methods are also changed when material is changed. However, the present invention can be adapted to all sorts of materials based on the above-stated ideas.

On the other hand, the shape of the transparent substrate which can be most technical-easily processed might be a simple slope shape as shown in FIG. 12. Taking this into consideration, it is considered that there is an optimal range with regard to the entire height (thickness of the transparent substrate) of the semiconductor light emitting element.

FIG. 13 shows the relation between the size of the semiconductor light emitting element and the height (thickness) of the GaP transparent substrate which are capable of forming a simple slope. Though other materials than GaP similarly have optimal ranges, the present invention can be adapted to the ranges of those other materials.

It is technically difficult to form the source of luminescence into a perfect point source in the actual semiconductor light emitting element. Even if the perfect point source can be generated, it is impossible to efficiently generate light in the light emitting layer due to increase in injection current density (specifically due to overflow of the injection current). Also, there occur problems of increases in heat value and resistance value.

The light emitting layer is actually formed of a surface shape having a certain expansion. At this time, it is not specifically necessary to strictly process or form the shape of the transparent substrate. The optical extraction efficiency to the outside is sufficiently improved if there is a portion processed into a slope shape.

In one embodiment of the present invention, a light emitting region in the main body is located near a center of the main body as viewed cross-sectionally.

This is based on the results considered above. That is, the height (thickness) of the transparent substrate has an optimal range. Specifically, the optimal range inevitably resides in the fact that the light emitting layer is located at an almost equal distance from the light emitting surface in the transparent substrate.

FIG. 14 is a schematic sectional view of one example of the semiconductor light emitting element of the above embodiment. The semiconductor light emitting element includes a p-type GaP transparent substrate 1401, a p-type GaP contact layer 1402, a p-type AlInP cladding layer 1403, an AlGaInP active layer 1404, an n-type AlInP cladding layer 1405, an n-type GaP contact layer 1406, an n-type GaP transparent substrate 1407, electrodes 1408, 1409 and a light emitting region 1410.

The light emitting region 1410 is limited by the optimal thickness of the transparent substrate and by arrangement of the electrodes for injecting electric current.

Moreover, as long as the light emitting region 1410 is located near the center of the main body, it may be considered whether there exists the shape processing of the p-type GaP transparent substrate 1401 and the n-type GaP transparent substrate 1407. However, desirably, the p-type GaP transparent substrate 1401 and the n-type GaP transparent substrate 1407 should be processed into a slope shape to obtain a greater effect.

In one embodiment of the present invention, the semiconductor light emitting element further comprises a current constriction structure for locating a light emitting region near a center of the main body as viewed cross-sectionally.

According to the semiconductor light emitting element of the embodiment, in order to locate the light emitting region at the end surface of the main body near the center of the end surface of the main body, the light emitting region is limited by the semiconductor layer for current constriction located near the light emitting layer.

It becomes possible to easily design the optimal size of the light emitting region by applying such a current constriction structure.

FIG. 15 is a schematic sectional view of one example of the semiconductor light emitting element of the above embodiment. The semiconductor light emitting element includes a p-type GaP transparent substrate 1501, a p-type GaP contact layer 1502, a p-type AlInP cladding layer 1503, an AlGaInP active layer 1504, an n-type AlInP cladding layer 1505, an n-type GaP contact layer 1506, an n-type GaP transparent substrate 1507, electrodes 1508, 1509 and a p-type GaP current blocking layer 1510.

FIG. 16A is a schematic sectional view of another example of the semiconductor light emitting element of the above embodiment. The semiconductor light emitting element includes a p-type GaP transparent substrate 1601, a p-type GaP contact layer 1602, a p-type AlInP cladding layer 1603, an AlGaInP active layer 1604, an n-type AlInP cladding layer 1605, an n-type GaP contact layer 1606, an n-type GaP transparent substrate 1607, electrodes 1608, 1609 and a p-type GaP current blocking layer 1610. FIG. 16B is a schematic perspective view of another example stated above.

In FIGS. 15, 16A and 16B, the light emitting region is limited by current constriction, and the shape of the transparent substrate is appropriately processed therefor. It is a matter of course that material for the above-stated construction is not limited to GaP of the present example. The designs similar to the above-stated designs can be adapted to all sorts of materials. The scope of the invention is not limited by any materials.

In one embodiment of the present invention, the light emitting layer has a structure stacked with semiconductor crystals comprised of two or more elements of gallium, aluminum, indium, phosphorus, arsenic, zinc, tellurium, sulfur, nitrogen, silicon, carbon and oxygen.

According to the semiconductor light emitting element of the embodiment, the wavelength of light emitted from the light emitting layer can be selected from a wide range of the infrared region to the near ultraviolet region. This is because the light emitting layer has a structure stacked with semiconductor crystals comprised of two or more elements of gallium, aluminum, indium, phosphorus, arsenic, zinc, tellurium, sulfur, nitrogen, silicon, carbon and oxygen.

The present invention provides a semiconductor light emitting element manufacturing method comprising the steps of:

successively layering a first conductive type semiconductor layer, a light emitting layer and a second conductive type semiconductor layer on a first conductive type semiconductor substrate;

bonding a second transparent substrate having transparency with respect to light emitted from the light emitting layer to an upper surface of the second conductive type semiconductor layer; and

bonding a first transparent substrate having transparency with respect to light emitted from the light emitting layer to a lower surface of the first conductive type semiconductor layer by removing the first conductive type semiconductor substrate after the step of bonding the second transparent substrate.

In this case, the first conductive type is p-type or n-type. The second conductive type is n-type when the first conductive type is p-type. The second conductive type is p-type when the first conductive type is n-type.

According to the semiconductor light emitting element manufacturing method stated above, it is possible to efficiently take light to the outside via the first transparent substrate and the second transparent substrate, so that the optical extraction efficiency can be improved. This is because the first transparent substrate, which has transparency with respect to light emitted from the light emitting layer, is bonded to the lower surface of the first conductive type semiconductor layer. Also, the second transparent substrate, which has transparency with respect to light emitted from the light emitting layer, is bonded to the upper surface of the second conductive type semiconductor layer.

In this case, the first and second conductive type semiconductor layers are each formed as a cladding layer for example, and the light emitting layer is made as a multiquantum well structure for example. Thereby, the number of layers that constitute the main body can be made the bare minimum.

The decrease in the number of layers constituting the main body allows preventing repetition of internal reflection. Therefore, it is possible to more efficiently take light to the outside via the first and second transparent substrates.

In one embodiment of the present invention, the second transparent substrate is bonded directly to the upper surface of the second conductive type semiconductor layer by processing under pressure and heating in the step of bonding the second transparent substrate.

According to the semiconductor light emitting element manufacturing method of the above embodiment, when bonding the second transparent substrate to the upper surface of the second conductive type semiconductor layer, the second transparent substrate and the second conductive type semiconductor layer are affixed together and bonded together by pressurization and heating.

Therefore, without using an adhesive for example, the second transparent substrate can easily be bonded directly to the upper surface of the second conductive type semiconductor layer.

In one embodiment of the present invention, the first transparent substrate is bonded directly to the lower surface of the first conductive type semiconductor layer by processing under pressure and heating in the step of bonding the first transparent substrate.

According to the semiconductor light emitting element manufacturing method of the above embodiment, when bonding the first transparent substrate to the lower surface of the first conductive type semiconductor layer, the first transparent substrate and the first conductive type semiconductor layer are affixed together and bonded together by pressurization and heating.

Therefore, without using an adhesive for example, the first transparent substrate can be bonded directly to the lower surface of the first conductive type semiconductor layer.

In one embodiment of the present invention, the second transparent substrate is bonded to the upper surface of the second conductive type semiconductor layer via a second transparent material layer that has transparency with respect to light emitted from the light emitting layer in the step of bonding the second transparent substrate.

According to the semiconductor light emitting element manufacturing method of the above embodiment, when bonding the second transparent substrate to the upper surface of the second conductive type semiconductor layer, the second transparent material layer is formed on the bonding plane (plane to be faced with the second conductive type semiconductor layer) of the second transparent substrate or on the upper surface of the second conductive type semiconductor layer, and then the second transparent substrate and the second conductive type semiconductor layer are bonded together via the second transparent material layer.

Use of the second transparent material layer for bonding of the second transparent substrate makes it possible to decrease a heating temperature in comparison with the case where the second transparent substrate is bonded directly to the upper surface of the second conductive type semiconductor layer. Also, selection of the second transparent material layer having an optimal resistivity makes it possible to decrease the resistance value at the bonding interface of the second conductive type semiconductor layer.

Selection of an appropriate refractive index of the second transparent material layer makes it possible to divert light, which is emitted from the light emitting layer, from the electrode that exists in the perpendicular direction. This allows manufacture of a semiconductor light emitting element having higher extraction efficiency.

For the second transparent material, ITO (indium tin oxide), ZnO (zinc oxide) and so on may be provided as a transparent material of adhesive conductor.

In one embodiment of the present invention, the first transparent substrate is bonded to the lower surface of the first conductive type semiconductor layer via a first transparent material layer that has transparency with respect to light emitted from the light emitting layer in the step of bonding the first transparent substrate.

According to the semiconductor light emitting element manufacturing method of the above embodiment, when bonding the first transparent substrate to the lower surface of the first conductive type semiconductor layer, the first transparent material layer is formed on the bonding plane (plane to be faced with the first conductive type semiconductor layer) of the first transparent substrate or on the lower surface of the first conductive type semiconductor layer. The first transparent substrate and the first conductive type semiconductor layer are bonded together via the first transparent material layer.

As described above, use of the first transparent material layer for the bonding of the first transparent substrate makes it possible to decrease a heating temperature in comparison with the case where the first transparent substrate is bonded directly to the lower surface of the first conductive type semiconductor layer. Also, selection of the first transparent material layer having an optimal resistivity makes it possible to decrease the resistance value of the bonding interface of the second conductive type semiconductor layer.

Moreover, selection of an appropriate refractive index of the first transparent material layer makes it possible to divert light, which is emitted from the light emitting layer, from the electrode that exists in the perpendicular direction. This allows manufacture of a semiconductor light emitting element having higher extraction efficiency.

For the first transparent material, ITO (indium tin oxide), ZnO (zinc oxide) and so on may be provided as a transparent material of adhesive conductor.

In one embodiment of the present invention, the second transparent substrate is bonded to the upper surface of the second conductive type semiconductor layer via a second metal material layer of an arbitrary shape in the step of bonding the second transparent substrate.

According to the semiconductor light emitting element manufacturing method of the above embodiment, when bonding the second transparent substrate to the upper surface of the second conductive type semiconductor layer, the second metal material layer is stacked on the bonding plane (plane to be faced with the second conductive type semiconductor layer) of the second transparent substrate or the upper surface of the second conductive type semiconductor layer, and then processed into an arbitrary shape. The second transparent substrate and the second conductive type semiconductor layer are bonded together via the arbitrarily shaped second metal material layer.

Use of the second metal material layer for the bonding of the second transparent substrate makes it possible to decrease a heating temperature in comparison with the case where the second transparent substrate is bonded directly to the upper surface of the second conductive type semiconductor layer. Also, use of the second metal material layer makes it possible to decrease the resistance value of the bonding interface of the second conductive type semiconductor layer.

Moreover, since it is possible to decrease the interface resistance of the second conductive type semiconductor layer, the carrier density of the second conductive type semiconductor layer can be made lower than the carrier density of the second transparent substrate. Thus, the transmittance of the second conductive type semiconductor layer is further increased, also improving the extraction efficiency of light.

The second metal material layer should desirably be selected from materials having a high reflectance in a wide wavelength region. When Ag is selected for example, Ag has a high reflectance throughout a wide wavelength region ranging from the near infrared region to the ultraviolet region. Therefore, Ag has an effect of reflecting light emitted from the light emitting layer, so that there is less loss in the light generated in the light emitting layer due to absorption or the like.

It is possible to make the metal material layer have a thickness of not greater than 50 nm in order to make light incident on the inside of the second transparent substrate. It is also possible to make a selection of forming the metal material layer into an arbitrary shape so that only minute part of light can be reflected or absorbed.

Au, Ag, Cu, Mo and so on can be enumerated as the material of the second metal material layer.

In one embodiment of the present invention, the first transparent substrate is bonded to the lower surface of the first conductive type semiconductor layer via a first metal material layer of an arbitrary shape in the step of bonding the first transparent substrate.

According to the semiconductor light emitting element manufacturing method of the above embodiment, when bonding the first transparent substrate to the lower surface of the first conductive type semiconductor layer, the first metal material layer is stacked on the bonding plane (plane to be faced with the first conductive type semiconductor layer) of the first transparent substrate or the lower surface of the first conductive type semiconductor layer, and then processed into an arbitrary shape. The first metal material layer having an arbitrary shape is formed on the bonding plane of the first transparent substrate or on the lower surface of the first conductive type semiconductor layer. The first transparent substrate and the second conductive type semiconductor layer are bonded together via the first metal material layer.

As described above, use of the first metal material layer for the bonding of the first transparent substrate makes it possible to decrease a heating temperature in comparison with the case where the first transparent substrate is bonded directly to the lower surface of the first conductive type semiconductor layer. Also, use of the first metal material layer makes it possible to decrease the resistance value at the bonding interface of the first conductive type semiconductor layer.

Moreover, since it is possible to decrease the interface resistance of the first conductive type semiconductor layer, the carrier density of the first conductive type semiconductor layer can be made lower than the carrier density of the first transparent substrate. Thus, the transmittance of the first conductive type semiconductor layer is further increased, also improving the extraction efficiency of light.

The first metal material layer should desirably be selected from materials having a high reflectance in a wide wavelength region. When Ag is selected for example, Ag has a high reflectance throughout a wide wavelength region ranging from the near infrared region to the ultraviolet region. Therefore, Ag has an effect of reflecting light from the light emitting layer, so that there is less loss in the light generated in the light emitting layer due to absorption or the like.

Moreover, it is possible to make the metal material layer have a thickness of not greater than 50 nm in order to make light incident on the inside of the first transparent substrate. It is also possible to make a selection of forming the metal material layer into an arbitrary shape so that only minute part of light can be reflected or absorbed.

In one embodiment of the present invention, the step of bonding the first transparent substrate and the step of bonding the second transparent substrate are different from each other in bonding methods.

According to the semiconductor light emitting element manufacturing method of the above embodiment, it is possible to carried out bonding of the first and second transparent substrates appropriately because the bonding process mutually differs between the step of bonding the first transparent substrate and the step of bonding the second transparent substrate.

For example, direct bonding is most suitable in terms of transmittance of light at the bonding interface. However, when direct bonding is applied to both surfaces, the structure and crystallinity of the element active layer may deteriorate due to a thermal history.

Combination of direct bonding with bonding via the material can minimize the thermal history.

In one embodiment of the present invention, the light emitting layer has a structure stacked with semiconductor crystals comprised of two or more elements of gallium, aluminum, indium, phosphorus, arsenic, zinc, tellurium, sulfur, nitrogen, silicon, carbon and oxygen.

According to this compound semiconductor light emitting diode, it is possible to select the wavelength of light, which is emitted from the light emitting layer, from a wide range of the infrared region to the near ultraviolet region. This is because the light emitting layer has a structure stacked with semiconductor crystals comprised of two or more elements of gallium, aluminum, indium, phosphorus, arsenic, zinc, tellurium, sulfur, nitrogen, silicon, carbon and oxygen.

According to the present invention, in short, it is possible to improve the external extraction efficiency of light by placing the first transparent substrate under the main body and by placing the second transparent substrate on top of the main body.

Also, it is possible to improve the external extraction efficiency of light by processing the first and second transparent substrates into a slope shape.

Further, it is possible to reduce the manufacturing cost because placing the first and second transparent substrates on the upper and lower sides of the main body makes it unnecessary to form the window layer constructed of a thick epitaxial layer.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic sectional view of a conventional semiconductor light emitting element;

FIG. 2 is a schematic sectional view of another conventional semiconductor light emitting element;

FIG. 3 is a schematic sectional view of a semiconductor light emitting element according to one embodiment of the present invention;

FIG. 4 is a schematic sectional view of a semiconductor light emitting element according to one embodiment of the present invention;

FIG. 5 is a schematic sectional view of a semiconductor light emitting element according to one embodiment of the present invention;

FIG. 6 is a graph showing results of comparing the light transmittance of a heavily doped GaP substrate and the light transmittance of a lightly doped GaP substrate;

FIG. 7 is a graph showing changes in the transmittance of the heavily doped GaP substrate and the lightly doped GaP substrate with respect to a change in the optical path length;

FIG. 8 is a schematic sectional view of a semiconductor light emitting element according to one embodiment of the present invention;

FIG. 9 is a schematic view of an essential part of a semiconductor light emitting element according to one embodiment of the present invention;

FIG. 10 is a schematic view of an essential part of a semiconductor light emitting element according to one embodiment of the present invention;

FIG. 11 is a schematic view of an essential part of a semiconductor light emitting element according to one embodiment of the present invention;

FIG. 12 is a schematic view of an essential part of a semiconductor light emitting element according to one embodiment of the present invention;

FIG. 13 is a graph showing the chip size dependency on optimal thickness (height) value of a transparent substrate;

FIG. 14 is a schematic sectional view of a semiconductor light emitting element according to one embodiment of the present invention;

FIG. 15 is a schematic sectional view of a semiconductor light emitting element according to one embodiment of the present invention;

FIG. 16A is a schematic sectional view of a semiconductor light emitting element according to one embodiment of the present invention;

FIG. 16B is a schematic perspective view of the semiconductor light emitting element of FIG. 16A;

FIG. 17 is a schematic sectional view of a LED of a first embodiment of the present invention;

FIG. 18 is one process chart of the manufacturing method of the LED of the first embodiment;

FIG. 19 is a schematic sectional view of a jig used for manufacturing the LED of the first embodiment;

FIG. 20 is a schematic sectional view of the LED of a second embodiment of the present invention;

FIG. 21 is a schematic sectional view of the LED of a third embodiment of the present invention;

FIG. 22A is one process chart of the manufacturing method of the LED of the third embodiment;

FIG. 22B is one process chart of the manufacturing method of the LED of the third embodiment;

FIG. 22C is one process chart of the manufacturing method of the LED of the third embodiment;

FIG. 22D is one process chart of the manufacturing method of the LED of the third embodiment; and

FIG. 22E is one process chart of the manufacturing method of the LED of the third embodiment.

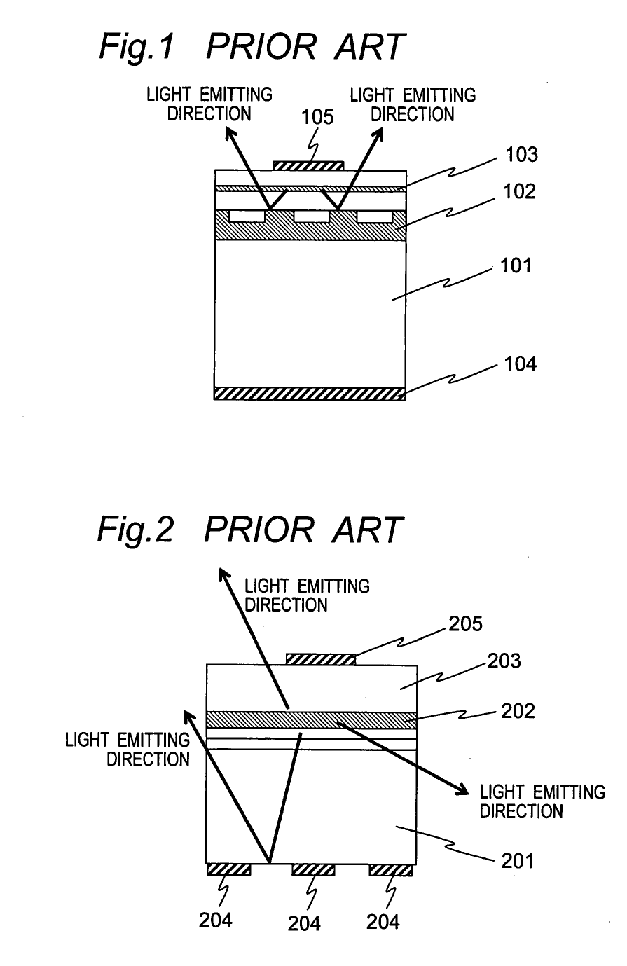

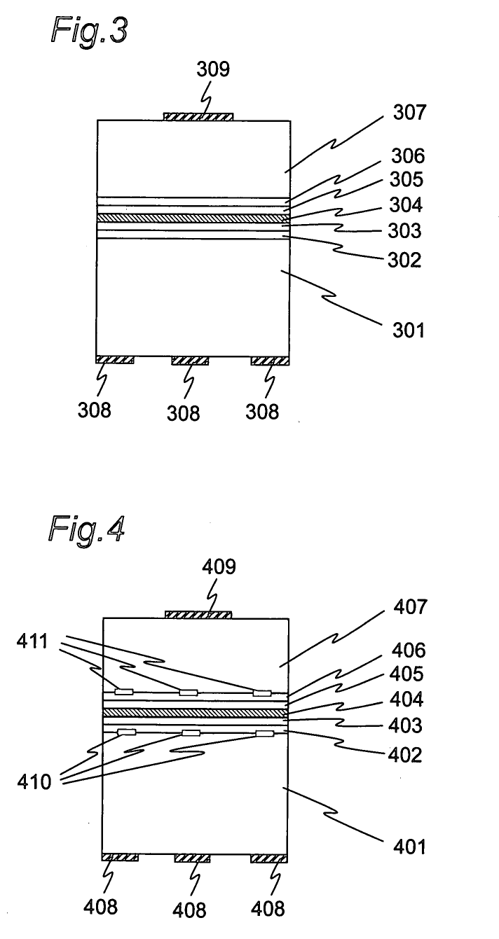

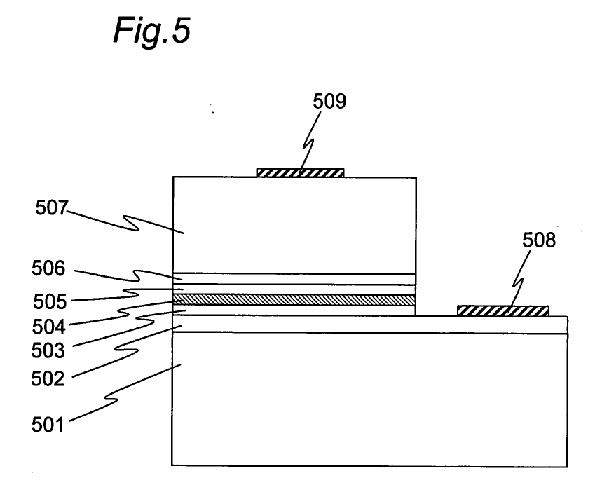

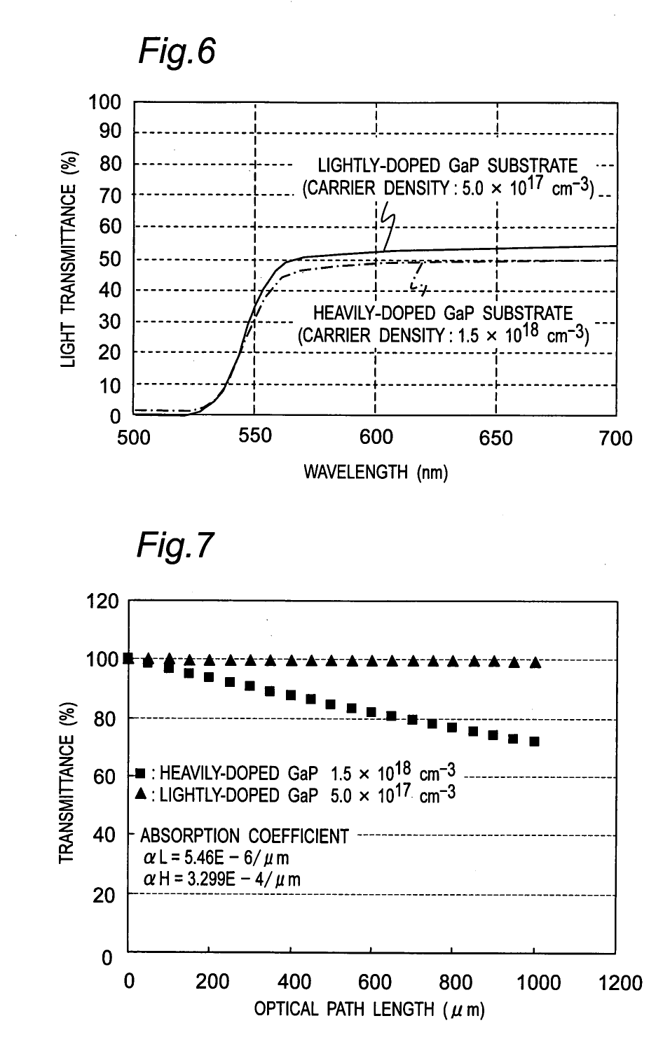

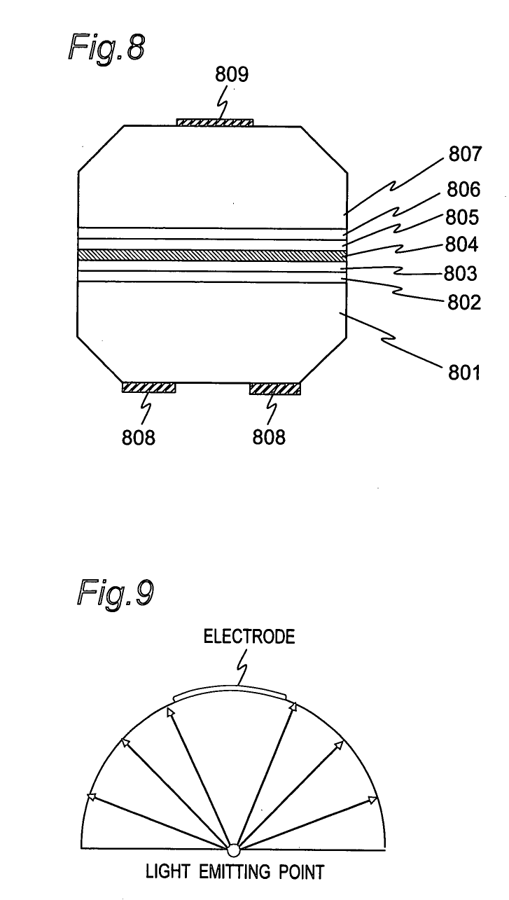

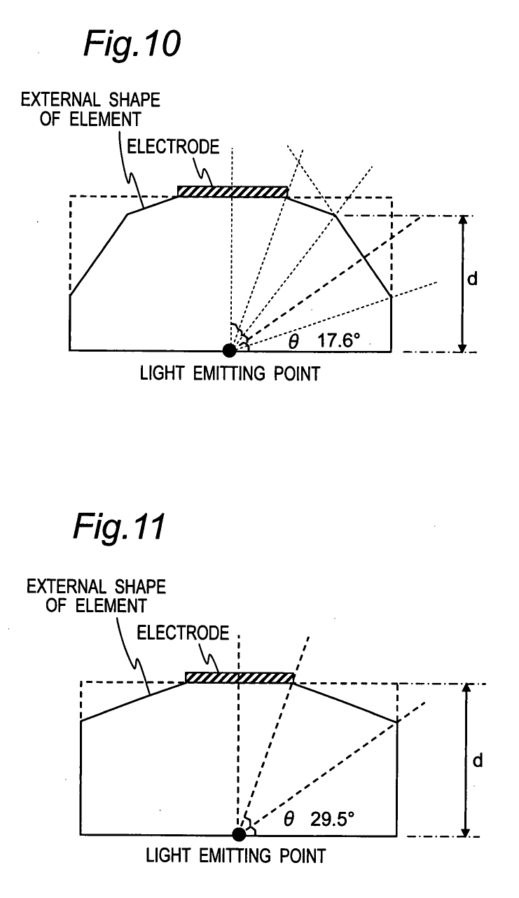

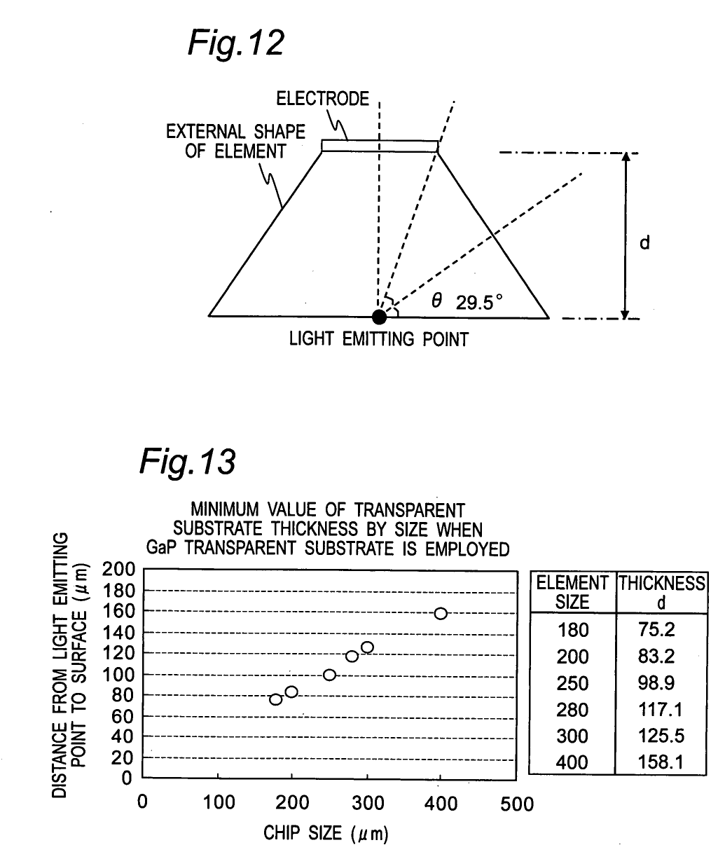

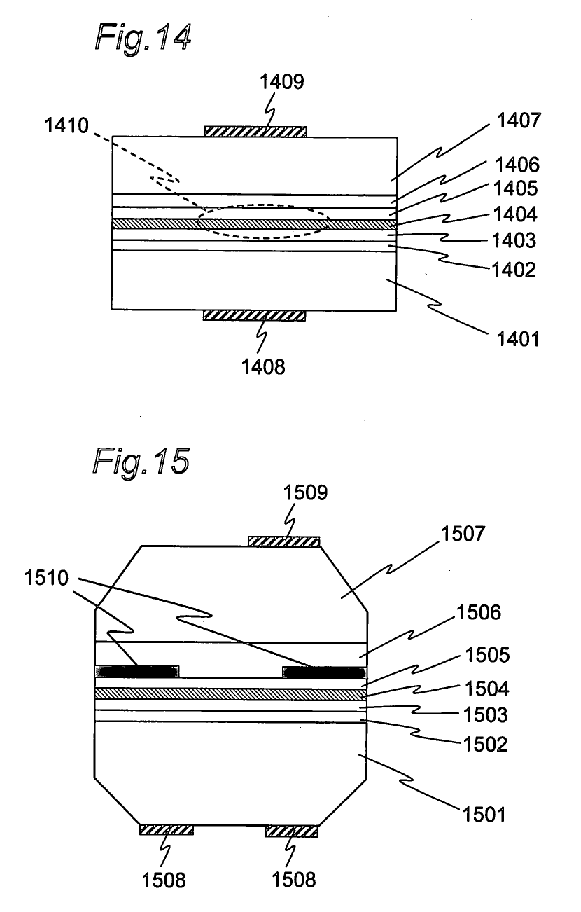

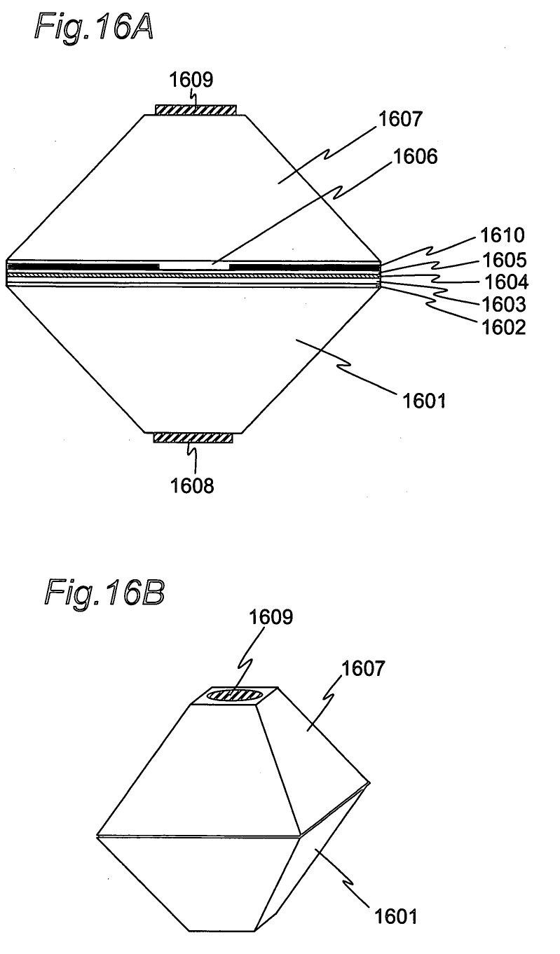

### DETAILED DESCRIPTION OF THE PREFERRED EMBODIMENTS

Description will be given below in detail to semiconductor light emitting elements, a manufacturing method therefor and compound semiconductor light emitting diodes of the present invention in embodiments with reference to drawings.

### First Embodiment

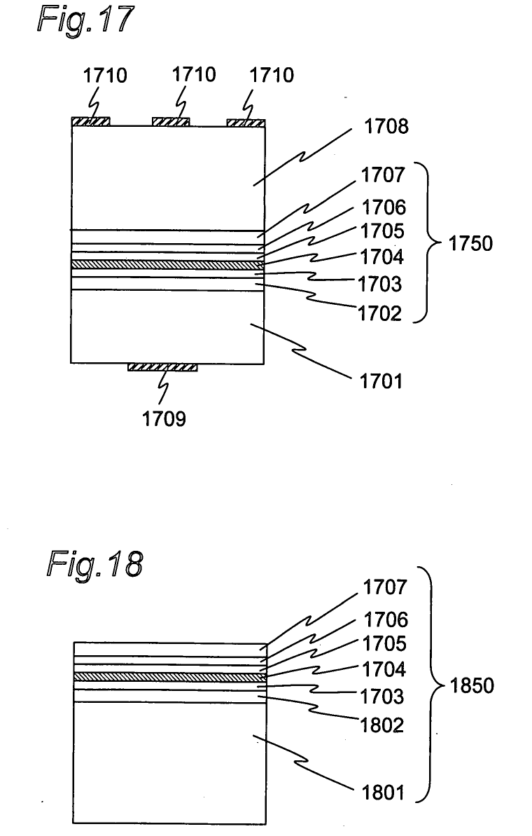

FIG. 17 shows a schematic sectional view of a LED according to a first embodiment of the present invention.

The LED has a main body 1750, an n-GaP transparent substrate 1701 placed under the main body 1750, and a p-GaP transparent substrate 1708 placed on top of the main body 1750. It is noted that the n-GaP transparent substrate 1701 is one example of the first transparent substrate, and that the p-GaP transparent substrate 1708 is one example of the second transparent substrate.

The main body 1750 is constructed of an n-Al_{0.6}Ga_{0.4}As current diffusion layer 1702, an n-Al_{0.5}In_{0.5}P cladding layer 1703, an AlGaInP active layer 1704, a p-Al_{0.5}In_{0.5}P cladding layer 1705, a p-GaInP interlayer 1706, and a p-GaP contact layer 1707. It is noted that the AlGaInP light emitting layer 1705 is one example of the light emitting layer. Moreover, the n-Al_{0.6}Ga_{0.4}As current diffusion layer 1702 and the n-Al_{0.5}In_{0.5}P cladding layer 1703 constitute examples of a first conductive type semiconductor layer. The p-Al_{0.5}In_{0.5}P cladding layer 1705, the p-GaInP interlayer 1706 and the p-GaP contact layer 1707 constitute examples of a second conductive type semiconductor layer.

The AlGaInP light emitting layer 1705 is a quaternary system light emitting layer that emits light of an emission wavelength of a red color. The n-GaP transparent substrate 1701 and the p-GaP transparent substrate 1708 have transparency with respect to light emitted from the AlGaInP light emitting layer 1705.

An electrode 1709 is formed beneath the n-GaP transparent substrate 1701. An electrode 1710 is formed on the p-GaP transparent substrate 1708.

The manufacturing method of the LED is described below.

First of all, as shown in FIG. 18, an n-GaAs buffer layer 1802, the n-Al_{0.6}Ga_{0.4}As current diffusion layer 1702, the n-Al_{0.5}In_{0.5}P cladding layer 1703, the AlGaInP active layer 1704, the p-Al_{0.5}In_{0.5}P cladding layer 1705, the p-GaInP interlayer 1706 and the p-GaP contact layer 1707 are layered in this order by using the MOCVD method on an n-GaAs substrate 1801 as one example of the first conductive type semiconductor substrate, so that a LED structure wafer 1850 is formed.

The AlGaInP active layer 1704 has a quantum well structure. More in detail, the AlGaInP active layer 1704 is formed by alternately layering an (Al_{0.05}Ga_{0.95})_{0.5}In_{0.5}p well layer and an (Al_{0.5}Ga_{0.5})_{0.5}In_{0.5}P barrier layer. Then, eight pairs of the (Al_{0.05}Ga_{0.95})_{0.5}In_{0.5}P well layer and the (Al_{0.5}Ga_{0.5})_{0.5}In_{0.5}P barrier layer are provided.

The substrate and the layers have thickness dimensions provided as: 250 μm of the n-GaAs substrate 1801; 1.0 μm of the GaAs buffer layer 1802; 5.0 μm of the n-Al_{0.6}Ga_{0.4}As current diffusion layer 1702; 1.0 μm of the n-Al_{0.5}In_{0.5}P cladding layer 1703; 0.5 μm of the AlGaInP active layer 1704; 1.0 μm of the p-Al_{0.5}In_{0.5}P cladding layer 1705; 1.0 μm of the p-GaInP interlayer 1706; and 4.0 μm of the p-GaP contact layer 1707.

In the substrate or the layers, Te is used as an n-type dopant, while Mg is used as a p-type dopant.

The substrate and the layers have carrier densities provided as: 1.0×10¹⁸ cm⁻³ of the n-GaAs substrate 1801; 5×10¹⁷ cm⁻³ of the n-GaAs buffer layer 1802; 1.0×10¹⁸ cm⁻³ of the n-Al_{0.6}Ga_{0.4}As current diffusion layer 1702; 5×10¹⁷ cm⁻³ of the n-Al_{0.5}In_{0.5}P cladding layer 1703; nondoped AlGaInP active layer 1704; 5×10¹⁷ cm⁻³ of the p-Al_{0.5}In_{0.5}P cladding layer 1705; 1.0×10¹⁸ cm⁻³ of the p-GaInP interlayer 1706; and 2.0×10¹⁸ cm⁻³ of the p-GaP contact layer 1707.

Next, a half dicing groove is formed by half dicing at a prescribed pitch on the epitaxial surface of the wafer 20. At this time, a depth of about 10 to 50 μm is appropriate for the half dicing groove in the point that the strength of the LED structure wafer is maintained.

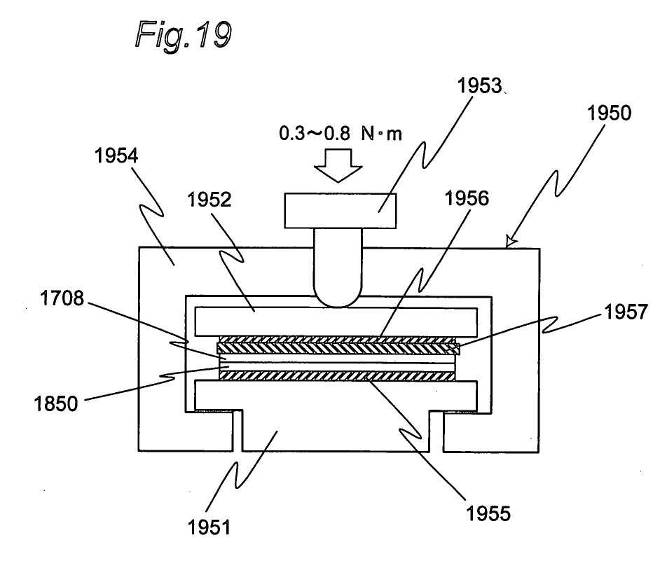

Next, the p-GaP transparent substrate 1708 is bonded directly to the epitaxial surface (upper surface of the p-GaP contact layer 1707) of the LED structure wafer 1850 by using an affixing jig 1950 made of quartz as shown in FIG. 19. The carrier density of the p-GaP transparent substrate 1708 is set at 5.0×10¹⁷ cm⁻³.

The jig 1950 has a first quartz plate 1951 that supports the wafer, a second quartz plate 1952 located on top of the first quartz plate 1951, and a pressurizing section 1953 that receives a force of a prescribed magnitude to pressurize the second quartz plate 1952.

The pressurizing section 1953 is guided in the vertical direction by a frame 1954 that has a roughly bracket-like shape when viewed from the front. The frame 1954 is engaged with the first quartz plate 1951, so that a force is appropriately transferred to the second quartz plate 1952 located between the first quartz plate 1951 and the pressurizing section 1953.

A carbon sheet 1955 is placed between the first quartz plate 1951 and the LED structure wafer 1850. A carbon sheet 1956 and a PBN (pyrolytic boron nitride) plate 1957 are placed between the second quartz plate 1952 and the p-GaP transparent substrate 1708.

By using the jig 1950 described above, the p-GaP transparent substrate 1708 is brought in contact with the p-GaP contact layer 1707, and then a force of, for example, 0.3 to 0.8 N·m is applied to the pressurizing section 1953 so as to make a compression force take effect on the contact plane of the p-GaP transparent substrate 1708 and the p-GaP contact layer 1707. The jig 1950 in the state is set in a heating furnace and heated for about 30 minutes at a temperature of about 800° C. under a hydrogen atmosphere. Then, the p-GaP transparent substrate 1708 is bonded directly to the LED structure wafer 1850.

Next, the LED structure wafer 1850 and the p-GaP transparent substrate 1708 are cooled down, and thereafter the jig 1950 is taken from the heating furnace. The n-GaAs substrate 1801 and the n-GaAs buffer layer 1802 are removed by dissolution with a liquid mixture of ammonia water, oxygenated water and water.

Next, the n-GaP transparent substrate 1701 is bonded directly to the surface (AlGaAs surface) exposed by removing the n-GaAs substrate 1801 and the n-GaAs buffer layer 1802. The bonding of the n-GaP transparent substrates 1701 is performed by processing under pressure and heating as in the case of the p-GaP transparent substrate 1708. Moreover, the carrier density of the n-GaP transparent substrate 1701 is set at 5.0×10¹⁷ cm⁻³.

Subsequently, electrode forming and chip-making process, which belong to the general manufacturing method of a semiconductor light emitting element, are carried out. Thereby, a high-intensity red LED of an emission wavelength of 640 nm as shown in FIG. 17 is completed.

According to the above-stated LED, the n-GaP transparent substrate 1701, which has transparency with respect to light emitted from the AlGaInP active layer 1704, is placed under the main body 1750. The p-GaP transparent substrate 1708, which has transparency with respect to the light emitted from the AlGaInP active layer 1704, is placed on top of the main body 1750. Thereby, light can efficiently be taken to the outside via the n-GaP transparent substrate 1701 and the p-GaP transparent substrate 1708. That is, the optical extraction efficiency can be improved.

In the present embodiment, an electrode material of AuSi/Au is selected as the material of the electrode 1709, and AuBe/Au is selected as the material of the electrode 1710. That is, in the present embodiment, the electrodes 1709 and 1710 are obtained by processing the AuSi/Au layer and the AuBe/Au layer into arbitrary shapes by the photolithography method and wet etching.

Moreover, after forming the electrodes 1709 and 1710, half dicing is carried out for separation into a prescribed chip size. At this time, by selecting a bevelable dicing blade, the side surface of the element can easily be processed into a slope shape. As a result, the side surface of one of the n-GaP transparent substrate 1701 and the p-GaP transparent substrate 1708 is allowed to have a slope shape.

The process with the bevelable dicing blade is carried out on a surface opposite from the surface that has previously undergone half dicing, this time. Thereby, the other side surface of the n-GaP transparent substrate 1701 and the p-GaP transparent substrate 1708 is allowed to have a slope shape.

The materials and techniques selected as above are not limited, and all sorts of materials and techniques of, for example, wet etching and dry etching can be selected. However, the technique of dicing seems to be appropriate in the point that it does not select (depend on) the material.

The manufacturing process of the present embodiment is applied to not only LED having the quaternary system light emitting layer made of AlGaInP but also any of the light emitting layer formed of semiconductor crystals.

### Second Embodiment

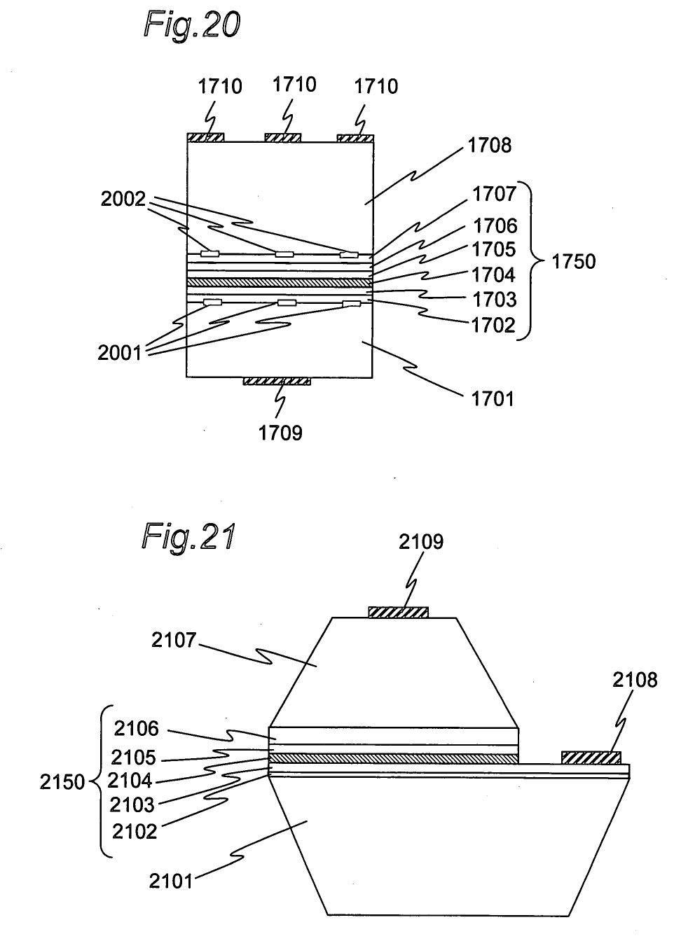

FIG. 20 shows a schematic sectional view of a LED according to a second embodiment of the present invention. In FIG. 20, the same components as those of the LED of the first embodiment shown in FIG. 17 are denoted by same reference numerals as those in FIG. 17, and no description is provided for them.

In the present embodiment, the n-GaP transparent substrate 1701 and the p-GaP transparent substrate 1708 are affixed to the main body 1750 via a metal.

That is, the LED of the present embodiment has a first metal thin film 2001 formed under the n-Al_{0.6}Ga_{0.4}As current diffusion layer 1702 and a second metal thin film 2002 formed on top of the p-GaP contact layer 1707. It is noted that the first metal thin film 2001 is one example of the first metal material layer, and the second metal thin film 2002 is one example of the second metal material layer.

The manufacturing method of the LED is described below.

First of all, a LED structure wafer 1850 is formed as in the case of the first embodiment. In the case of the present embodiment, it is not necessity to preparatorily form a groove on the LED structure wafer 1850.

Next, by using the vapor deposition method or the sputtering method, a thin film is formed on the epitaxial surface (upper surface of the p-GaP contact layer 1707) of the LED structure wafer 1850 or on the bonding plane (plane to be faced with the LED structure wafer 1850) of the p-GaP transparent substrate 1708.

The thin film may be made of either one of gold, silver, aluminum and titanium; or a compound of gold, silver, aluminum or titanium; or an alloy that contains at least one of gold, silver, aluminum and titanium.

Next, the second metal thin film 2002 is formed by processing the thin film into an arbitrary shape with the photolithography method and wet etching. At this time, the second metal thin film 2002 has an area of not larger than 10% of the element area in forming the element. Thereby, the loss of light at the bonding interface can be suppressed to a minimum.

Next, the p-GaP contact layer 1707 and the p-GaP transparent substrate 1708 are bonded together by means of the bonding jig 1950 (see FIG. 19) as in the case of first embodiment. At this time, the p-GaP contact layer 1707 and the p-GaP transparent substrate 1708 can be bonded together in a heating process carried out for about 30 minutes at a temperature of about 400 to 500° C. under a hydrogen atmosphere.

Next, the substrate and the buffer layer are removed as in the case of first embodiment. Thereafter, the first metal thin film 2001 is formed on the lower surface of the n-Al_{0.6}Ga_{0.4}As current diffusion layer 1702 or on the bonding plane (plane to be faced with the LED structure wafer 1850) of the n-GaP transparent substrate 1702 as in the case of the second metal thin film 2002.

Subsequently, as in the case of the p-GaP transparent substrate 1708 sated above, affixation of the n-GaP transparent substrate 1702 is carried out. Thereafter, electrode forming and chip-making process, which belong to the general manufacturing method of a semiconductor light emitting element, are carried out, so that the LED of the present embodiment is completed.

### Third Embodiment

FIG. 21 is a schematic sectional view of a LED according to a third embodiment of the present invention.

The LED of the present embodiment corresponds to a case where one of two transparent substrates is made of an insulator. That is, the LED of the present embodiment has a main body 2150, a glass substrate 2101 placed under the main body 2150, and an n-GaP transparent substrate 2107 placed on top of the main body 2150. It is noted that the glass substrate 2101 is one example of the first transparent substrate, and the n-GaP transparent substrate 2107 is one example of the first transparent substrate.

The main body 2150 is constructed of a p-GaP contact layer 2102, a p-AlInP cladding layer 2103, an AlGaInP active layer 2104, an n-AlInP cladding layer 2105 and an n-GaP contact layer 2106. It is noted that the AlGaInP active layer 2104 is one example of the light emitting layer. Moreover, the p-GaP contact layer 2102 and the p-AlInP cladding layer 2103 constitute one example of the first conductive type semiconductor layer. Then, the n-AlInP cladding layer 2105 and the n-GaP contact layer 2106 constitute one example of the second conductive type semiconductor layer.

The p-AlInP cladding layer 2103 has an exposed part. An electrode 2108 is formed on top of the exposed part. Moreover, an electrode 2109 is formed on top of the n-GaP transparent substrate 2107.

The manufacturing method of the LED is described below.

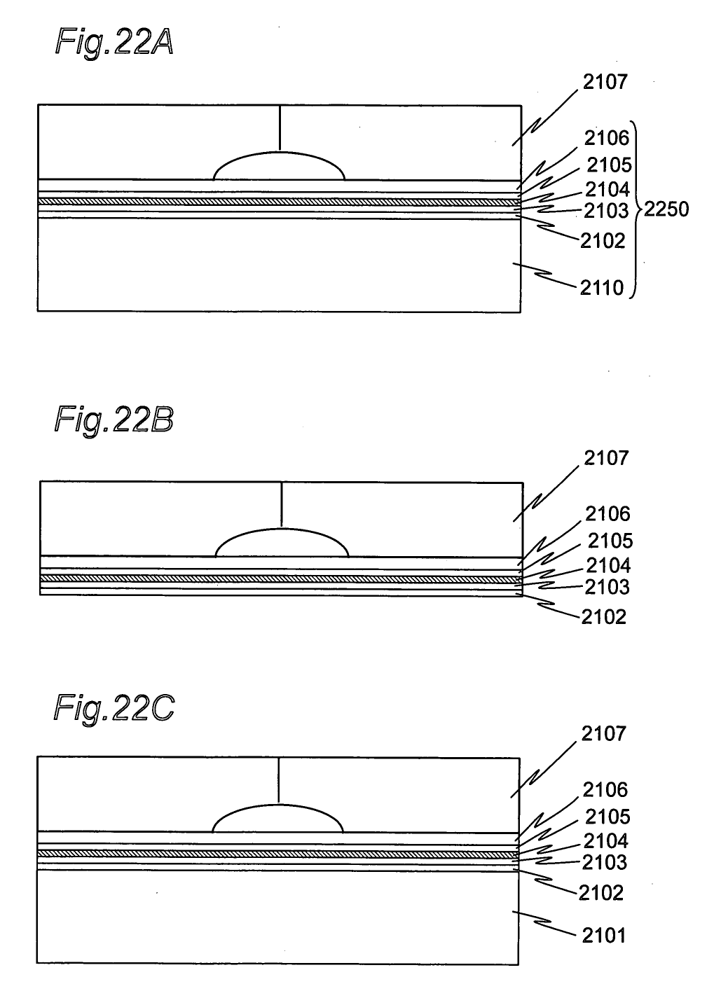

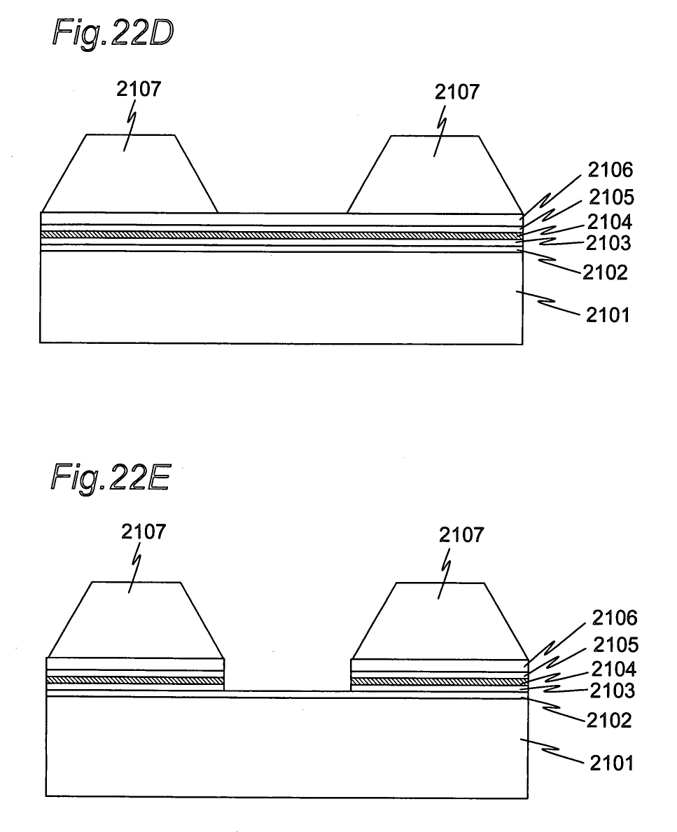

First of all, as shown in FIG. 22A, the p-GaP contact layer 2102, the p-AlInP cladding layer 2103, the AlGaInP active layer 2104, the n-AlInP cladding layer 2105 and the n-GaP contact layer 2106 are layered in this order by the MOCVD method on a p-GaAs substrate 2111 as one example of the first conductive type semiconductor substrate, so as to form a LED structure wafer 2250.

Next, the n-GaP transparent substrate 2107 is bonded directly to the epitaxial surface (upper surface of the n-GaP contact layer 2105) of the LED structure wafer 2250. That is, the bonding of the n-GaP transparent substrate is carried out without using an adhesive or the like.

The direct bonding of the n-GaP transparent substrate 2107 can be carried out by a method similar to that of the first embodiment.

The surface of the n-GaP transparent substrate has preliminarily been processed for patterning by the photolithography method (using a mask of an oxide of SiO₂ etc.), wet etching (by aqua regia, sulfuric acid, oxygenated water mixture solution, etc.) so that a prescribed chip shape can be provided.

Next, the p-GaAs substrate 2111 is removed to provide a state as shown in FIG. 2. Thereafter, the glass substrate 2101 is bonded, with epoxy resin for example, to the removal surface (lower surface of the p-GaP contact layer 2102) of the GaAs substrate, as shown in FIG. 22C.

Next, half dicing is carried out along the pattern of the n-GaP transparent substrate 2107, so that the side surfaces of the n-GaP transparent substrate 2107 are formed to have a slope shape, as shown in FIG. 22D.

The half dicing is carried out by a bevelable blade. Thereby, the side surfaces of the n-GaP transparent substrate 2107 can be formed to have a slope shape.

Next, etching is carried out until the p-GaP contact layer 2102 is exposed with the patterned n-GaP transparent substrate 2107 used as a mask. Etching is conducted by using a mixed liquor of phosphoric acid, sulfuric acid, oxygenated water and water.

Next, as shown in FIG. 21, the electrode 2108 is formed on the exposed portion of the p-AlInP cladding layer 2103, and the electrode 2109 is formed on the n-GaP transparent substrate 2107, and thereafter dicing of the glass substrate 2101 is carried out from the lower surface side, so that the LED of the present embodiment is completed.

As one similar to the LED of the present embodiment, there is a LED wherein the transparent substrate and the semiconductor layer, which is affixed to the substrate, have mutually different conductive types, and wherein no electrical connection is provided between the transparent substrate and the semiconductor layer.

This LED is a LED in which the n-GaP transparent substrate 1701 in the first embodiment is replaced by the p-GaP transparent substrate.

Specifically, the LED is obtained by directly bonding of a p-GaP transparent substrate (carrier density: 5.0×10¹⁷ cm⁻³) for example, as one example of the first transparent substrate, to the n-Al_{0.6}Ga_{0.4}As current diffusion layer 1702 exposed by the removal of the n-GaAs substrate 1801 in the first embodiment.

There is no electrical connection between the p-GaP transparent substrate and the n-Al_{0.6}Ga_{0.4}As current diffusion layer 1702 at the normal LED driving voltage (not higher than 10 V).

The first through third embodiments of the present invention have been described above, the present invention is not limited to the quaternary system LED but applicable to all sorts of semiconductor light emitting elements.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

What is claimed is:

1. A semiconductor light emitting element comprising:
a main body having a first conductive type semiconductor layer, a light emitting layer provided on the first conductive type semiconductor layer and a second conductive type semiconductor layer provided on the light emitting layer;
a first transparent substrate placed directly or indirectly under the main body and having transparency with respect to light emitted from the light emitting layer; and
a second transparent substrate placed directly or indirectly on top of the main body and having transparency with respect to the light emitted from the light emitting layer.

2. The semiconductor light emitting element as set forth in claim 1, wherein
the first transparent substrate is comprised of a first conductive type semiconductor, and the second transparent substrate is comprised of a second conductive type semiconductor.

3. The semiconductor light emitting element as set forth in claim 1, wherein
the first transparent substrate is of a second conductive type; or
the second transparent substrate is of a first conductive type; or
the first transparent substrate is of the second conductive type, and the second transparent substrate is of the first conductive type.

4. The semiconductor light emitting element as set forth in claim 2, wherein
at least one of the first transparent substrate and the second transparent substrate has a carrier density of not higher than 2.5×10¹⁸ cm³.

5. The semiconductor light emitting element as set forth in claim 1, wherein
at least one of the first transparent substrate and the second transparent substrate is comprised of an insulator.

6. The semiconductor light emitting element as set forth in claim 1, wherein
at least one of the first transparent substrate and the second transparent substrate has a slope surface inclined to the upper surface of the light emitting layer.

7. The semiconductor light emitting element as set forth in claim 1, wherein
a light emitting region in the main body is located near a center of the main body as viewed cross-sectionally.

8. The semiconductor light emitting element as set forth in claim 1, further comprising:
a current constriction structure for locating a light emitting region near a center of the main body as viewed cross-sectionally.

9. The semiconductor light emitting element as set forth in claim 1, wherein
the light emitting layer has a structure stacked with semiconductor crystals comprised of two or more elements of gallium, aluminum, indium, phosphorus, arsenic, zinc, tellurium, sulfur, nitrogen, silicon, carbon and oxygen.

10. A semiconductor light emitting element manufacturing method comprising the steps of:
successively layering a first conductive type semiconductor layer, a light emitting layer and a second conductive type semiconductor layer on a first conductive type semiconductor substrate;
bonding a second transparent substrate having transparency with respect to light emitted from the light emitting layer to an upper surface of the second conductive type semiconductor layer; and
bonding a first transparent substrate having transparency with respect to light emitted from the light emitting layer to a lower surface of the first conductive type semiconductor layer by removing the first conductive type semiconductor substrate after the step of bonding the second transparent substrate.

11. The semiconductor light emitting element manufacturing method as set forth in claim 10, wherein
the second transparent substrate is bonded directly to the upper surface of the second conductive type semiconductor layer by processing under pressure and heating in the step of bonding the second transparent substrate.

12. The semiconductor light emitting element manufacturing method as set forth in claim 10, wherein
the first transparent substrate is bonded directly to the lower surface of the first conductive type semiconductor layer by processing under pressure and heating in the step of bonding the first transparent substrate.

13. The semiconductor light emitting element manufacturing method as set forth in claim 10, wherein
the second transparent substrate is bonded to the upper surface of the second conductive type semiconductor layer via a second transparent material layer that has transparency with respect to light emitted from the light emitting layer in the step of bonding the second transparent substrate.

14. The semiconductor light emitting element manufacturing method as set forth in claim 10, wherein
the first transparent substrate is bonded to the lower surface of the first conductive type semiconductor layer via a first transparent material layer that has transparency with respect to light emitted from the light emitting layer in the step of bonding the first transparent substrate.

15. The semiconductor light emitting element manufacturing method as set forth in claim 10, wherein
the second transparent substrate is bonded to the upper surface of the second conductive type semiconductor layer via a second metal material layer of an arbitrary shape in the step of bonding the second transparent substrate.

16. The semiconductor light emitting element manufacturing method as set forth in claim 10, wherein
the first transparent substrate is bonded to the lower surface of the first conductive type semiconductor layer via a first metal material layer of an arbitrary shape in the step of bonding the first transparent substrate.

17. The semiconductor light emitting element manufacturing method as set forth in claim 11, wherein
the step of bonding the first transparent substrate and the step of bonding the second transparent substrate are different from each other in bonding methods.

18. A compound semiconductor light emitting diode manufactured by using the semiconductor light emitting element manufacturing method set forth in claim 10, wherein
the light emitting layer has a structure stacked with semiconductor crystals comprised of two or more elements of gallium, aluminum, indium, phosphorus, arsenic, zinc, tellurium, sulfur, nitrogen, silicon, carbon and oxygen.

19. The semiconductor light emitting element as set forth in claim 3, wherein
at least one of the first transparent substrate and the second transparent substrate has a carrier density of not higher than 2.5×10¹⁸ cm⁻³.

20. The semiconductor light emitting element manufacturing method as set forth in claim 11, wherein
the first transparent substrate is bonded directly to the lower surface of the first conductive type semiconductor layer by processing under pressure and heating in the step of bonding the first transparent substrate.

21. The semiconductor light emitting element manufacturing method as set forth in claim 13, wherein
the step of bonding the first transparent substrate and the step of bonding the second transparent substrate are different from each other in bonding methods.
